(19) United States
(12) Patent Application Publication
(10) Pub. No.: US 2023/0247786 A1
(43) Pub. Date: Aug. 3, 2023

(54) DISPLAY APPARATUS

(71) Applicant: PANASONIC INTELLECTUAL PROPERTY MANAGEMENT CO., LTD., Osaka (JP)

(72) Inventors: Shinichiro NAKAMURA, Kanagawa (JP); Tomoaki YAMAMOTO, Kanagawa (JP)

(73) Assignee: PANASONIC INTELLECTUAL PROPERTY MANAGEMENT CO., LTD., Osaka (JP)

(21) Appl. No.: 18/101,767

(22) Filed: Jan. 26, 2023

(30) Foreign Application Priority Data
Feb. 3, 2022 (JP) 2022-015494

(51) Int. Cl. H05K 5/04

(52) U.S. Cl. CPC H05K 5/04; B60K 35/00

(57) ABSTRACT

A display panel is attached to a central portion of the rear surface. A chassis has a rear plate covering the display panel from behind and has a side wall surrounding a side surface of the display panel from a periphery of the rear plate and extending frontward. A front frame is provided between a front end of the side wall and a periphery of the rear surface and is made of a resin. A rear portion of the front frame is attached to the chassis by holding the side wall of the chassis from a side of the front end. The front portion of the front frame has an attachment surface to which the periphery of the rear surface is attached.

### BACKGROUND

### 1. Field

The present disclosure relates to display apparatuses.

### 2. Description of the Related Art

It is desired that display apparatuses have a thin bezel. It is also desired to secure strength of a display apparatus mounted on a vehicle in order to withstand vibration caused by the vehicle. For this purpose, an integrated structure with chassis insertion in which the frame is held by the chassis is used (see, for example, patent literature 1).

[Patent literature 1] JP2020-181023

In the display apparatus of patent literature 1, the chassis is manufactured by die casting, and the rear surface of the glass lens of the display panel is directly and adhesively attached to the chassis. In the case the chassis is manufactured by a method other than die casting, the flatness of a part of the surface may be lower than in the chassis manufactured by die casting. When the rear surface of a glass lens is directly and adhesively attached to the surface of the chassis with a low flatness, the display panel may not be attached to the chassis uniformly. This could result in reduced contrast or quality degradation by causing a lack of black uniformity in the liquid crystal of the display panel. It is desired to maintain the quality of display even if the flatness of the chassis of the display apparatus is low.

### SUMMARY

The present disclosure addresses the above-described issue, and a purpose thereof is to provide a technology of maintaining the quality of display even if the flatness of a chassis is low.

A display apparatus according to an embodiment of the present disclosure includes: a transparent plate having a front surface that faces frontward and a rear surface that faces rearward; a display panel attached to a central portion of the rear surface; a chassis that has a rear plate covering the display panel from behind and has a side wall surrounding a side surface of the display panel from a periphery of the rear plate and extending frontward; and a resin frame provided between a front end of the side wall and a periphery of the rear surface. The resin frame has a rear portion and a front portion located in front of the rear portion. The rear portion is attached to the chassis by holding the side wall from a side of the front end, and the front portion has an attachment surface to which the periphery of the rear surface is attached.

### BRIEF DESCRIPTION OF THE DRAWINGS

Embodiments will now be described, by way of example only, with reference to the accompanying drawings that are meant to be exemplary, not limiting, and wherein like elements are numbered alike in several figures, in which:

FIG. 1 shows a structure in a vehicle cabin of a vehicle according to the embodiment;

FIGS. 2A-2B show a structure of the display apparatus of FIG. 1;

FIG. 3 is a partial cross-sectional view showing a portion of FIG. 2B on an enlarged scale;

FIGS. 4A-4F show various exemplary structures of the front frame and the chassis of FIG. 2B;

FIGS. 5A-5B show various exemplary structures of the front frame and the chassis of FIG. 2B; and

FIG. 6 is a partial cross-sectional view showing a portion of the display apparatus according to a variation on an enlarged scale.

### DETAILED DESCRIPTION

The invention will now be described by reference to the preferred embodiments. This does not intend to limit the scope of the present invention, but to exemplify the invention.

A summary of the embodiment of the present disclosure will be given before describing the embodiment in specific details. The embodiment relates to a display apparatus mounted on a vehicle. The display apparatus is configured such that, for example, a display panel is accommodated inside a chassis with an open front, and a frame (hereinafter, “front frame”) having a shape of a framework is attached to the opening on the front side of the chassis. The front frame is a designed component and is a component touched by a passenger. The front frame is made of a resin. In the case the front frame and the chassis are separately structured, it is necessary to make the front frame thin in order to make the bezel thin. However, merely making the front frame thin may cause the front frame to be easily detached from the chassis due to an external force such as vibration. It is therefore difficult to secure at least one of strength or rigidity of the display apparatus. Therefore, the front frame has been configured to have a certain thickness in order to secure strength and rigidity. This have resulted in some cases in a certain constraint imposed on size reduction and thin bezel configuration of the product and in smaller flexibility of the design.

It is conceivable to form the chassis and the front frame by, for example, insert molding in order to secure strength while at the same ensuring a thin bezel configuration. This will cause the display apparatus to have an integrated structure with chassis insertion in which the front frame is held by the chassis. In the case the chassis is manufactured by die casting, the glass lens of the display panel is, for example, adhesively attached to the chassis by an adhesive member. In an integrated structure with chassis insertion, the front frame is not easily detached from the chassis in the presence of an external force even if the front frame is thin so that the strength is secured.

In the case the chassis is manufactured by die casting, it is necessary to renew the mold at a certain frequency. In consideration of the cost and versatility, it is desired to manufacture the chassis by a method other than die casting. For example, the chassis may be manufactured by using a sheet metal. In the case the glass lens is adhesively attached to the chassis by an adhesive member, on the other hand, a high flatness is required on the surface of attachment to the glass lens. In the case of a chassis made of a sheet metal, it is more difficult to secure the flatness than in the case of a diecast chassis. If the flatness of the surface of adhesive attachment between the glass lens and the chassis is lowered, the display panel may not be attached to the chassis uniformly. This could cause a lack of black uniformity in the liquid crystal of the display panel and so result in reduced contrast or quality degradation. Further, the adhesive member may be exfoliated easily if the flatness of the surface of adhesive attachment is lowered. Flatness indicates irregularity, or warp, or undulation, or distortion of the surface. Flatness is defined in, for example, JISG3193, but the definition is not limited thereto. Flatness may be a value presented by the width that results when a target is sandwiched from above and below by two completely flat surfaces.

In the display apparatus according to the embodiment, the forefront end of the chassis is covered by the front frame, and the glass lens is fixed to the chassis via the front frame. The front frame is manufactured by using a resin so that a high flatness of the surface of attachment to the glass lens is ensured. The terms “parallel” and “orthogonal” in the following description not only encompass completely parallel or orthogonal but also encompass slightly off-parallel and slightly non-orthogonal within the margin of error.

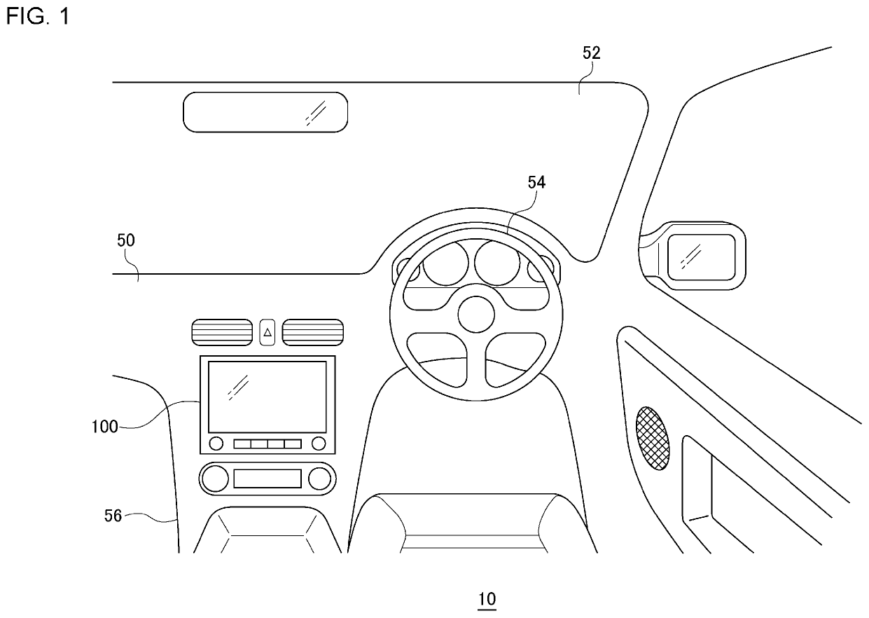

FIG. 1 shows a structure in a vehicle cabin of a vehicle 10. A windshield 52 is provided in front of a dashboard 50 provided frontward in the vehicle cabin. A steering wheel 54 is provided to the right of the dashboard 50, but the steering wheel 54 may be provided to the left of the dashboard 50. A center console 56 extending vertically is provided in the central portion of the dashboard 50, and the display apparatus 100 is set within the center console 56. Further, only the lower portion of the display apparatus 100 may be set in the center console so that the entire design of the display apparatus 100 may be exposed outside. The display apparatus 100 is, for example, included in an electronic appliance such as a navigation apparatus. The display apparatus 100 may be configured to display a map image, etc. The display apparatus 100 may be a meter display provided in front of the steering.

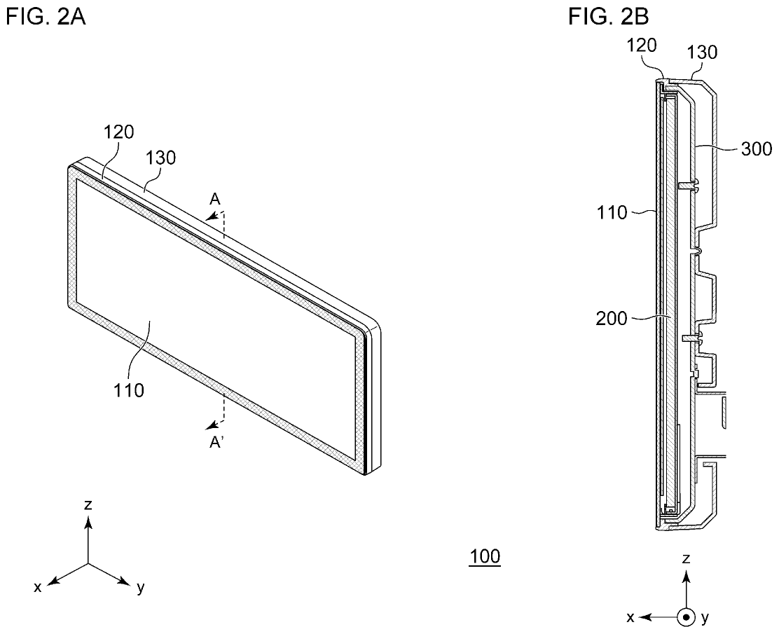

FIGS. 2A-2B show a structure of the display apparatus 100. As shown in FIGS. 2A-2B, an orthogonal coordinate system formed by an x axis, y axis, and z axis is defined. The x axis and y axis are orthogonal to each other. The z axis is perpendicular to the x axis and y axis and extends in the vertical direction of the display apparatus 100. The positive directions of the x axis, y axis, and z axis are defined in the directions of arrows in FIGS. 2A-2B, and the negative directions are defined in the directions opposite to those of the arrows. The positive direction of the x axis may be referred to as “frontward”, “front side”, the negative direction of the x axis may be referred to as “rearward”, “rear side”, the positive direction of the y axis may be referred to as “right”, “rightward”, the negative direction of the y axis may be referred to as “left”, “leftward”, the positive direction of the z axis may be referred to as “above”, “upper side”, and the negative direction of the z axis may be referred to as “below”, “lower side”. It can therefore be said that the x axis extends in the longitudinal direction, the y axis extends in the horizontal direction, and the z axis extends in the vertical direction.

FIG. 2A is a perspective view showing the appearance of the display apparatus 100. FIG. 2B is a cross-sectional view of the display apparatus 100 along the A-A′ line of FIG. 2A. A plate-shaped glass lens 110 extending on the y-z plane is provided on the front surface of the display apparatus 100. The glass lens 110 is a light transmissive member and is made of a glass. A resin may be used instead of a glass to form the glass lens 110, and the glass lens 110 may be referred to as a transparent member. The glass lens 110 may be referred to as a transparent plate. The periphery of the glass lens 110 is surrounded by the front frame 120. The front frame 120 is, for example, rectangular. The front frame 120 may have a round shape. The entirety of the periphery of the glass lens 110 may be surrounded by the front frame 120, or a portion of the periphery may not be surrounded by the front frame 120. For example, the upper side and the left and right sides of the periphery of the glass lens 110 may be surrounded by the front frame 120, and a different member may be attached to the underside. The distance between the periphery of the glass lens 110 and the front frame 120 is defined as a bezel width. Reducing the bezel width results in a thin bezel configuration. For example, the bezel width is configured to be 10 mm or less.

The front frame 120 is provided on a portion of the front surface and a portion of the side surfaces of the display apparatus 100. A rear frame 130 is provided behind the front frame 120 to cover the side surfaces and the rear surface of the display apparatus 100. In this way, the side surfaces and the rear surface of the display apparatus 100 are covered by the front frame 120 and the rear frame 130.

Further, the front frame 120 and the rear frame 130 are made of a resin. A resin material having a sufficient breaking extension or a material having a linear coefficient of expansion close to that of the chassis 300 described later is used. This is to prevent cracks due to temperature change.

A display panel 200 is provided to face the glass lens 110 inside the display apparatus 100 surrounded by the glass lens 110, the front frame 120, and the rear frame 130. An example of the display panel 200 is a liquid crystal panel. The display panel 200 emits a display light toward the glass lens 110. The side surfaces and the rear surface of the display panel 200 are covered by the chassis 300. The chassis 300 is a sheet metal chassis and is manufactured by using iron. The front end of the chassis 300 is connected to the front frame 120. The front side of the front frame 120 is connected to the glass lens 110, and the rear side of the front frame 120 is connected to the rear frame 130.

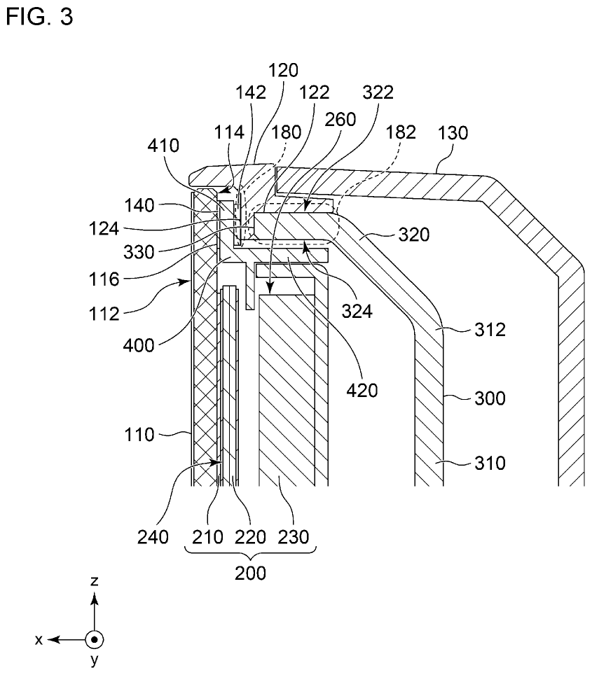

In the following description, FIG. 3 to describe the structure of FIG. 2B in further detail. FIG. 3 is a partial cross-sectional view showing a portion of FIG. 2B on an enlarged scale. FIG. 3A shows the upper portion of the display apparatus 100, and the lower portion, the left portion, and the right portion may have a similar structure. The glass lens 110 has a front surface 112 that faces frontward and a rear surface 114 that faces rearward. The display panel 200 is attached to the central portion of the rear surface 114 of the glass lens 110.

The display panel 200 includes an optical adhesive sheet 210, a liquid crystal panel 220, and a backlight unit 230. The liquid crystal panel 220 and the backlight unit 230 of the display panel 200 has a plate shape extending on the y-z plane, and the liquid crystal panel 220 is provided in front of the backlight unit 230. Further, the liquid crystal panel 220 is adhesively attached to the rear surface 114 of the glass lens 110 via the optical adhesive sheet 210. By illuminating the liquid crystal panel 220 with the backlight unit 230, the image displayed on the liquid crystal panel 220 is output as a display light toward the glass lens 110. Therefore, the front surface of the liquid crystal panel 220 is called a display surface 240. The display surface 240 has a rectangular shape on the y-z plane.

Further, side surfaces 260 are provided on the x-y plane and the z-x plane in the backlight unit 230. For example, four side surfaces 260 are included in the display panel 200.

The chassis 300 includes a rear plate 310 and a side wall 320, which are formed in an integrated manner. The rear plate 310 of the chassis 300 has a plate shape extending on the y-z plane. The central portion of the rear plate 310 covers the backlight unit 230 from behind. The portion of the rear plate 310 that does not cover the rear side of the backlight unit 230 is a periphery 312, and the periphery 312 is provided with a side wall 320 extending toward the front side. The side wall 320 surrounds the side surface 260 of the display panel 200. The side wall 320 has an outer side surface 322 and an inner side surface 324. The inner side surface 324 faces the side surface 260 of the display panel 200, and the outer side surface 322 faces the direction opposite to that of the inner side surface 324. The combination of the rear plate 310 and the side wall 320 like this has a shape of a box with an open front. The forefront portion of the side wall 320 is a front end 330, and the front end 330 has a framework shape on the y-z plane.

The front frame 120 is provided between the front end 330 of the side wall 320 of the chassis 300 and a periphery 116 of the rear surface 114 of the glass lens 110. The front frame 120 includes a front portion 180 and a rear portion 182, and the front portion 180 is located in front of the rear portion 182. The rear portion 182 is attached to the chassis 300 by holding the side wall 320 from the side of the front end 330. The portion of the rear portion 182 holding the side wall 320 from the side of the front end 330 is an insertion groove 122. The structure of the front frame 120 and the chassis 300 like this is an integrated structure with chassis insertion. The integrated structure with chassis insertion is manufactured by insert molding of the front frame 120 and the chassis 300. Meanwhile, an attachment surface 124 is provided in the front portion 180. As mentioned above, the front frame 120 is made of a resin so that the flatness of the attachment surface 124 can be higher than the flatness of the chassis 300.

A resin support member 400 is inserted between the front frame 120 and the glass lens 110. The support member 400 is comprised of a first portion 410 and a second portion 420 integrated with each other. The first portion 410 has a framework shape on the y-z plane and is provided between the attachment surface 124 of the front frame 120 and the rear surface 114 of the glass lens 110. The front surface of the first portion 410 is adhesively attached to the rear surface 114 of the glass lens 110 by a first adhesive member 140. The rear surface of the first portion 410 is adhesively attached to the attachment surface 124 by a second adhesive member 142. The first adhesive member 140 and the second adhesive member 142 are, for example, double-sided tapes. The second portion 420 is provided to extend rearward from the inner portion of the first portion 410. The second portion 420 supports the backlight unit 230. The support member 400 is used to adhesively attach the cover of the backlight unit 230 to the glass lens 110. Depending on the shape of the backlight unit 230, etc., however, the support member 400 may be omitted. In this way, the periphery 116 of the rear surface 114 of the glass lens 110 is directly or indirectly attached to the attachment surface 124.

For thin bezel configuration, the front frame 120 is configured to have a small thickness. Generally, when the front frame 120 is configured to have a small thickness, the front frame 120 is easily detached from the chassis 300 in the presence of an external force so that the strength is lowered. In this embodiment, however, an integrated structure with chassis insertion is employed so that the front frame 120 is not easily detached from the chassis 300 in the presence of an external force even if the front frame 120 has a small thickness so that the strength of the front frame 120 and the chassis 300 is secured. This can meet the requirements for strength and thin bezel configuration at the same time.

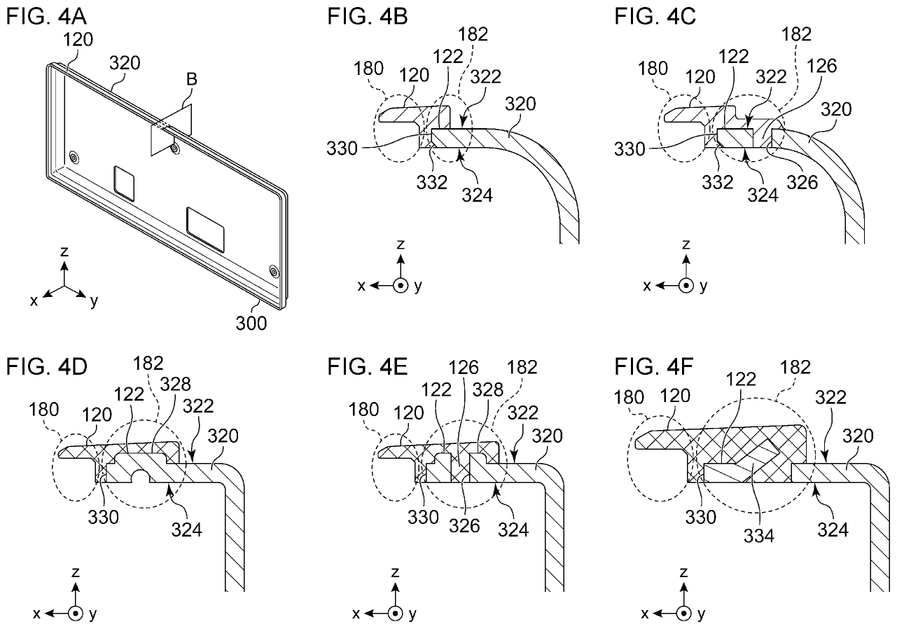

A description will be given below of a variation of the structure for making it more difficult for the front frame 120 to be detached from the chassis 300 even if an external force is exerted. FIGS. 4A-4F show various exemplary structures of the front frame 120 and the chassis 300. FIG. 4A is a perspective view of the structure of the combination of the front frame 120 and the chassis 300 seen from front. An area B is defined, and partial cross-sectional views along the area B are shown in FIG. 4B through FIG. 4F.

FIG. 4B shows that the front end 330 of the side wall 320 of the chassis 300 is chamfered to form an inclined surface 332 between the front end 330 and the inner side surface 324. At least a portion of the insertion groove 122 of the rear portion 182 is in contact with the chamfered portion in the front end 330, i.e., the inclined surface 332.

FIG. 4C shows that a through hole 326 extending between the outer side surface 322 and the inner side surface 324 is provided in the side wall 320 of the chassis 300. At least a portion of the insertion groove 122 of the rear portion 182 is also located in the through hole 326 as a portion 126 filling the through hole. FIG. 4D shows that a projection 328 that projects outward from the outer side surface 322 is provided in the side wall 320 of the chassis 300. The projection 328 is formed by, for example, by half punching. At least a portion of the insertion groove 122 of the rear portion 182 covers the projection 328.

FIG. 4E shows that a through hole 326 extending between the outer side surface 322 and the inner side surface 324 is provided in the side wall 320 of the chassis 300. Further, a projection 328 that projects outward along the edge of the through hole 326 is provided on the outer side surface 322 of the side wall 320. At least a portion of the insertion groove 122 of the rear portion 182 is also provided in the through hole 326 as a portion 126 filling the through hole and covers the projection 328.

FIG. 4F shows that the side wall 320 of the chassis 300 is cut and raised to provide a tab portion 334. The tab portion 334 extends outward from the display panel 200 (not shown) and extends rearward. At least a portion of the insertion groove 122 of the rear portion 182 covers the tab portion 334. The structures of FIG. 4B-4F increase the area of contact between the front frame 120 and the chassis 300 and also increase the strength of adhesion between the front frame 120 and the chassis 300.

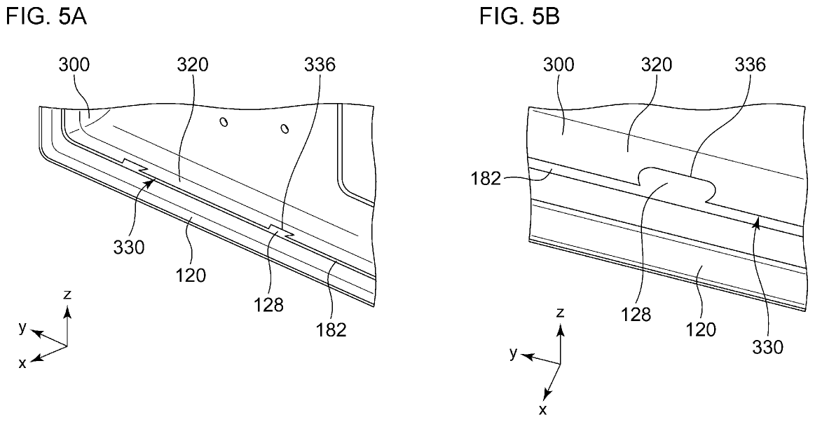

FIGS. 5A-5B show various exemplary structures of the front frame 120 and the chassis 300. FIGS. 5A-5B are perspective views of the structures of the combination of the front frame 120 and the chassis 300 seen from below. FIG. 5A shows that a dent 336 extending rearward is provided in the front end 330 of the side wall 320 of the chassis 300. The dent 336 is shaped such that the transversal width is progressively larger away from the front end 330. A least a portion of the rear portion 182 is also located in the dent 336 as an anchor 128.

FIG. 5B shows that the shape of the dent 336 is different from that of FIG. 5A. The dent 336 has a stadium shape or a capsule shape. A least a portion of the rear portion 182 is also located in the dent 336 as an anchor 128.

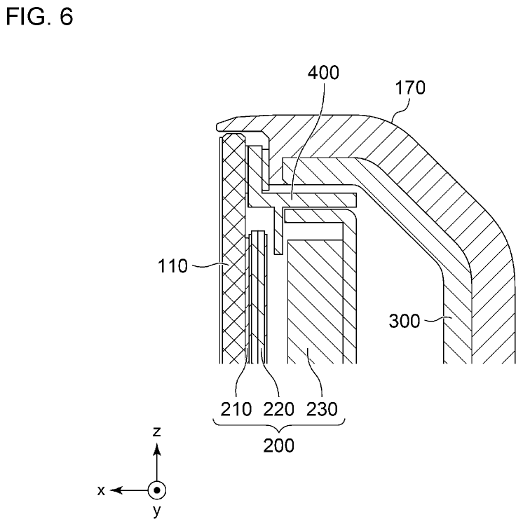

The display apparatus 100 described so far is covered by the front frame 120 and the rear frame 130. The front frame 120 and the rear frame 130 may be molded to be integrated. FIG. 6 is a partial cross-sectional view showing a portion of the display apparatus 100 according to a variation on an enlarged scale. The configuration of FIG. 6 is similarly shown in FIG. 3, and the glass lens 110, the display panel 200, the chassis 300, and the support member 400 are the same as those of FIG. 3. An integrated frame 170 is a member in which the front frame 120 and the rear frame 130 of FIG. 3 are integrated and is made of a resin.

According to the embodiment, the front frame made of a resin has an attachment surface to which the periphery of the rear surface of the glass lens is attached so that the attachment surface is ensured to have a high flatness even if the flatness of the chassis is low. Further, the attachment surface has a high flatness even if the flatness of the chassis is low so that the quality of display can be maintained even if the flatness of the chassis is low. Further, the rear portion of the front frame is attached to the chassis by holding the side wall from the side of the front end, and so it is ensured that the front frame is not easily detached from the chassis even if an external force is exerted. Further, the front frame is not easily detached from the chassis even if an external force is exerted so that the strength of the display apparatus is secured. Further, the strength of the display apparatus is secured so that the display apparatus can be configured to have a thin bezel. Further, the strength of the display apparatus is secured while at the same time the display apparatus is configured to have a thin bezel. Accordingly, the flexibility of design can be improved. Further, the glass lens is attached to the highly flat front frame and, at the same time, the front frame and the chassis are configured to have an integrated structure with chassis insertion. Accordingly, a thin bezel configuration can be realized.

Further, a sheet metal chassis is used so that the versatility can be improved. Further, the cost of using a sheet metal chassis can be reduced. Further, the chassis has a inclined surface so that the area of contact between the front frame and the chassis can be increased. Further, the area of contact between the front frame and the chassis is increased so that the strength of adhesion between the front frame and the chassis can be improved. Further, a through hole is provided in the chassis so that the friction between the front frame and the chassis can be increased. Further, the friction between the front frame and the chassis is increased so that the strength of adhesion between the front frame and the chassis can be improved.

Further, a projection is provided in the chassis so that the friction between the front frame and the chassis can be increased. Further, the chassis has a tab so that the friction between the front frame and the chassis can be increased. Further, a dent is provided in the chassis so that the friction between the front frame and the chassis can be increased. Further, the front frame and the rear frame surround the chassis so that the chassis can be protected. Further, the front frame and the rear frame are molded to be integrated so that the number of components can be reduced.

One embodiment of the present disclosure is summarized below. A display apparatus according to an embodiment of the present disclosure includes: a transparent plate having a front surface that faces frontward and a rear surface that faces rearward; a display panel attached to a central portion of the rear surface; a chassis that has a rear plate covering the display panel from behind and has a side wall surrounding a side surface of the display panel from a periphery of the rear plate and extending frontward; and a resin frame provided between a front end of the side wall and a periphery of the rear surface. The resin frame has a rear portion and a front portion located in front of the rear portion, the rear portion is attached to the chassis by holding the side wall from a side of the front end, and the periphery of the rear surface is attached to the front portion.

According to the embodiment, the resin frame made of a resin has an attachment surface to which the periphery of the rear surface of the transparent plate is attached so that the quality of display can be maintained even if the flatness of the chassis is low.

The chassis may be a sheet metal chassis. In this case, a sheet metal chassis is used so that the versatility can be improved.

The front end may have an inclined surface, and at least a portion of the rear portion may be in contact with the inclined surface. In this case, the chassis has an inclined surface so that the strength of adhesion between the frame and the chassis can be increased.

The side wall may have a through hole extending through the side wall, and at least a portion of the rear portion may be located in the through hole. In this case, a through hole is provided in the chassis so that the strength of adhesion between the frame and the chassis can be increased.

The side wall may have a projection, and the rear portion may cover the projection. In this case, a projection is provided in the chassis so that the strength of adhesion between the frame and the chassis can be improved.

The side wall may have a tab extending outward from the display panel and extending rearward, and the rear portion may cover the tab. In this case, the chassis has a tab so that the strength of adhesion between the frame and the chassis can be improved.

The front end may have a dent extending rearward, and at least a portion of the rear portion may be located in the dent. In this case, a dent is provided in the chassis so that the strength of adhesion between the frame and the chassis can be improved.

The resin frame is a front frame, and the display apparatus further comprises a rear frame that covers the chassis from behind. Further, the front frame and the rear frame surround the chassis so that the chassis can be protected.

The front frame and the rear frame may be molded to be integrated. Further, the front frame and the rear frame are molded to be integrated so that the number of components can be reduced.

Described above is an explanation based on an exemplary embodiment. The embodiment is intended to be illustrative only and it will be understood by those skilled in the art that various modifications to constituting elements and processes could be developed and that such modifications are also within the scope of the present invention.

While various embodiments have been described herein above, it is to be appreciated that various changes in form and detail may be made without departing from the spirit and scope of the invention(s) presently or hereafter claimed.

### CROSS-REFERENCE TO RELATED APPLICATION

This application is based upon and claims the benefit of priority from the prior Japanese Patent Application No. 2022-015494, filed on Feb. 3, 2022, the entire contents of which are incorporated herein by reference.

What is claimed is:

1. A display apparatus comprising:
a transparent plate having a front surface that faces frontward and a rear surface that faces rearward;
a display panel attached to a central portion of the rear surface;
a chassis that has a rear plate covering the display panel from behind and has a side wall surrounding a side surface of the display panel from a periphery of the rear plate and extending frontward; and
a resin frame provided between a front end of the side wall and a periphery of the rear surface, wherein
the resin frame has a rear portion and a front portion located in front of the rear portion,
the rear portion is attached to the chassis by holding the side wall from a side of the front end, and
the front portion has an attachment surface to which the periphery of the rear surface is attached.

2. The display apparatus according to claim 1, wherein
the chassis is a sheet metal chassis.

3. The display apparatus according to claim 1, wherein
the front end has an inclined surface, and
at least a portion of the rear portion is in contact with the inclined surface.

4. The display apparatus according to claim 1, wherein
the side wall has a through hole extending through the side wall, and
at least a portion of the rear portion is located in the through hole.

5. The display apparatus according to claim 1, wherein
the side wall has a projection, and
the rear portion covers the projection.

6. The display apparatus according to claim 1, wherein
the side wall has a tab extending outward from the display panel and extending rearward, and
the rear portion covers the tab.

7. The display apparatus according to claim 1, wherein
the front end has a dent extending rearward, and
at least a portion of the rear portion is located in the dent.

8. The display apparatus according to claim 1, wherein
the resin frame is a front frame, and
the display apparatus further comprises a rear frame that covers the chassis from behind.

9. The display apparatus according to claim 8, wherein
the front frame and the rear frame are molded to be integrated.
